(19) United States
(12) Patent Application Publication
(10) Pub. No.: US 2021/0155479 A1
(43) Pub. Date: May 27, 2021

(54) BORON NITRIDE NANOTUBE SYNTHESIS VIA LASER DIODE

(71) Applicant: BNNT, LLC, Newport News, VA (US)

(72) Inventors: Jonathan C. STEVENS, Williamsburg, VA (US); Thomas W. HENNEBERG, Newport News, VA (US); Kevin C. JORDAN, Newport News, VA (US); Michael W. SMITH, Newport News, VA (US); R. Roy WHITNEY, Newport News, VA (US)

(21) Appl. No.: 17/059,360

(22) PCT Filed: May 29, 2019
(86) PCT No.: PCT/US2019/034372

§ 371 Date: Nov. 27, 2020

Related U.S. Application Data
(60) Provisional application No. 62/677,502, filed on May 29, 2018.

(51) Int. Cl. C01B 21/064; H01L 21/02

(52) U.S. Cl. CPC C01B 21/0641; H01L 21/0254; B82Y 30/00; C01P 2004/13; H01L 21/02606

(57) ABSTRACT

High quality Boron Nitride Nanotubes (BNNTs) may be synthesized by heating a boron melt target via one or more laser diodes, including laser diode stacks. The use of a diode stack and beam shaping optics to irradiate the boron melt eliminates the need for a conventional laser cavity as has been employed with previous embodiments. The diode arrangements facilitate managing power distribution on the born melt(s), nitrogen gas flows, and blackbody radiation that drive the BNNT self-assembly process. These parameters may be used for controlling the proportions and characteristics of boron species, a-BN particles, h-BN nanocages, and h-BN nano sheets in the as-synthesized BNNT material while enhancing the quality of the BNNTs.

This application claims priority to U.S. Provisional Patent Application 62/677,502, filed May 29, 2018, and incorporated by reference in its entirety.

### STATEMENT REGARDING GOVERNMENT SUPPORT

None.

### FIELD OF THE INVENTION

The present disclosure relates to methods of producing boron nitride nanotubes (BNNTs) with one or more laser diodes.

### BACKGROUND

Boron nitride nanotubes (BNNTs) have been made by multiple processes including electric arc, laser, inductively coupled plasma (ICP), radio frequency direct induction (DI), and chemical vapor deposition (CVD). High-quality BNNTs, i.e. few wall, high crystallinity, high aspect ratio and catalyst free, are usually made by laser, ICP, or DI processes. However, the BNNT material produced by these processes typically contains small particles of boron, amorphous boron nitride (a-BN), hexagonal boron nitride (h-BN) nanocages (sometimes referred to as nanococoons), and h-BN nanosheets. These species are often undesirable in numerous applications, as they can interfere with various properties of the bulk BNNTs. For the highest yield of BNNT and control of the relative amounts and characteristics of h-BN nanocages and h-BN nanosheets present, laser-driven BNNT synthesis processes have demonstrated the best performance. A primary challenge for the laser-driven processes has been their relatively high cost and low energy efficiency, particularly as measured by the final cost of BNNT material.

What is needed, then, are laser-driven BNNT synthesis processes that generate high-quality BNNTs, with few undesirable species, and at reasonable costs and high energy efficiencies.

### SUMMARY

The current disclosure describes the synthesis of high-quality Boron Nitride Nanotubes (BNNTs) via heating a boron melt target with light from one or more laser diodes, including laser diode stacks and other configurations of laser diodes. The use of one or more laser diodes and beam shaping optics to irradiate the boron melt eliminates the need for a conventional laser cavity as has been employed with previous embodiments using, for example, a CO₂ laser, a fiber laser, or free-electron laser. The diode stack facilitates preferred embodiments that allow for management of the power distribution on the boron melt, nitrogen gas flows, and blackbody radiation that drive BNNT self-assembly processes. Managing these parameters is important for controlling the amount of boron particles, a-BN particles, and h-BN nanosheets in the as-synthesized BNNT material while producing higher-quality BNNTs. The detailed characteristics of the final processed BNNT material has proven important for improving performance of the processed BNNT material in end-use applications, such as, but not limited to, composites, cryopumps, catalysts, vibration damping, and thermal management in, e.g., electronics and aircraft.

Some embodiments of the present approach may take the form of a laser diode apparatus for producing boron nitride nanotube (BNNT) materials. Embodiments of the apparatus may include a chamber with a boron feedstock mounting surface to support a boron melt; a nitrogen gas supply system configured to feed nitrogen gas into the chamber upstream of the mounting surface, and flow the nitrogen gas through the chamber in a first direction; at least one laser diode configured to emit a beam into the chamber and irradiate a heating location on a boron melt on the mounting surface at a selected power, wherein the selected power is adjustable; and at least one optical shaping element configured to adjust the cross-section of the beam at the heating location. Embodiments of the apparatus may also include a growth zone region downstream of the mounting surface in the first direction, the growth zone region configured for BNNT self-assembly downstream of the mounting surface in the first direction. In some embodiments, the mounting surface may include a boron nitride-containing layer. The boron nitride-containing layer may include other boron and nitride species, without departing from the present approach.

In some embodiments, there may be a plurality of laser diodes, instead of a single laser diode. The laser diodes may be arranged to irradiate different heating locations on the boron melt. In some embodiments, all or a portion of the laser diodes may form a laser diode stack. Some embodiments may include more than one laser diodes stack. It should be appreciated that other embodiments may include combinations and configurations of laser diodes other than as specifically described herein with respect to the demonstrative embodiments, without departing from the present approach.

Various optical shaping elements may be used. Some embodiments may include one or more refractive optical elements. Some embodiments may include one or more fiber optic elements. Some embodiments may include one or more reflective optical elements. An optical shaping element may be custom-built for a particular embodiment. It should also be appreciated that embodiments may feature combinations of optical shaping elements other than as specifically described with respect to the demonstrative embodiments, without departing from the present approach.

In some embodiments, a spherical reflector may be included to reflect light and/or blackbody radiation toward a region downstream of the mounting surface. As described in more detail below, the spherical reflector may be configured for a specific embodiment, and may not be precisely spherical and/or not form a complete sphere for a given embodiment. The spherical reflector may be positioned around at least a portion of the mounting surface. In some embodiments, the spherical reflector includes gaps or holes for beams to pass through. In some embodiments, the spherical reflector may have one or more nitrogen gas flow channels upstream of the mounting surface. A nitrogen gas flow channel may be configured to direct nitrogen gas in the first direction, and may be used to control the flow velocity.

The present approach may, for some embodiments, include a BNNT material harvesting mechanism in the apparatus. For example, the harvesting mechanism may include one or more wire meshes, metal sheets, and/or rotating cylinders.

The present approach may also take the form of a laser diode process for synthesizing boron nitride nanotube (BNNT) material. Embodiments of the process may include feeding nitrogen gas to a chamber in a first direction and at a flow rate; forming a boron melt on a mounting surface; irradiating a first heating location of the boron melt with a beam from at least one laser diode, the beam having a beam power and a beam cross-section at the heating location; collecting BNNT material having, among other possible chemical species, BNNTs that self-assemble downstream of the boron melt; and adjusting at least one of the flow rate, the beam power, and the beam cross-section during the irradiation, the adjustment corresponding to consumption of the boron melt. In some embodiments, a boron nitride-containing layer may be formed on the mounting surface. In some embodiments, the boron melt may be replenished with a boron feedstock. The rate of replenishment may vary, depending on the particular embodiment.

In some embodiments, adjusting the flow rate, the beam power, and/or the beam cross-section during the irradiation may be accomplished by, among other ways, changing the position of at least one optical shaping element. It should be appreciated that an embodiment may include one or more fiber optic elements. Some embodiments may include one or more reflective optical elements. An optical shaping element may be custom-built for a particular embodiment. It should also be appreciated that embodiments may feature combinations of optical shaping elements other than as specifically described with respect to the demonstrative embodiments, without departing from the present approach

In some embodiments, light and/or blackbody radiation may be reflected onto the boron melt. The reflected light and/or blackbody radiation may target a different heating location than the beam in some embodiments. One or more spherical reflectors may be used to reflect light and/or blackbody radiation. In some embodiments, the spherical reflector may have one or more nitrogen gas flow channels that may be used to direct nitrogen gas into the chamber in the first direction.

As described herein, processes according to the present approach may feature one or more laser diodes. Some embodiments having more than one laser diode irradiate different heating locations on the boron melt. In some embodiments, all or a portion of the laser diodes may form a laser diode stack. Some embodiments of the present approach may include more than one laser diodes stack. For example, in some embodiments a second heating location of the boron melt may be irradiated with a second beam from a second laser diode. The second beam may have a second beam power and a second beam cross-section. In some embodiments, the second laser diode may form a laser diode stack. At least one of the second laser diode beam power and the second laser diode beam cross-section may be adjusted during irradiation. As a non-limiting example, the position of a second optical shaping element may be changed to make an adjustment. In some embodiments, more than one beam may be adjusted during irradiation. Various combinations and configurations of laser diodes, other than those specifically described herein, may be used without departing from the present approach.

### BRIEF DESCRIPTION OF THE DRAWINGS

FIG. 1 illustrates an embodiment of a boron melt target assembly illuminated by light from diode stacks and a spherical reflector.

FIG. 2 illustrates an embodiment of a boron melt target assembly within a nitrogen gas pressure chamber with two diode stacks and optical shaping elements.

FIG. 3 illustrates an embodiment of a boron melt target assembly illuminated by light from a single source of diode stack(s) with a reflective optical beam shaping element.

FIG. 4 illustrates an embodiment of a boron melt target assembly illuminated by light from two separate diode stacks.

FIG. 5 illustrates an embodiment of a boron melt target assembly illuminated by light from two separate diode stacks and having convection gas flow control.

FIG. 6 illustrates an embodiment of a boron melt target assembly within a nitrogen gas pressure chamber with two separate diode stacks, a boron replenishment feeder, a cooling mechanism, and a harvesting mechanism.

FIGS. 7A and 7B illustrate changes to a boron melt and a beam cross-sectional shape during processing.

### DETAILED DESCRIPTION

Laser-driven processes have typically been used to synthesize high-quality BNNTs, where the number of walls range from one to ten (with most being two-walled and three-walled), the length-to-diameter ratios are typically ten thousand to one or higher, the BNNTs are catalyst free, and the BNNTs are highly crystalline with very few defects (less than one defect per one hundred diameters of length). An additional reason laser-driven synthesis has typically been used is that it offers the preferred methods for managing the amount of boron particles, a-BN particles, h-BN nanocages, and h-BN nanosheets in the as-synthesized BNNT material while enhancing the quality of the BNNTs. Further, the characteristics, e.g. size, relative ratios and fraction of total mass of the boron particles, a-BN particles, h-BN nanocages, and h-BN nanosheets can be managed when utilizing laser driven processes and controlling the power distribution and intensity on the boron melt, size of the boron melt, flow of nitrogen over the boron melt including velocity distribution and temperature profile, and the pressure of the nitrogen gas surrounding the boron melt. Lasers in the multi-kilowatt range needed for synthesizing BNNTs in large scale continuous manufacturing processes are complicated, expensive, and electrically inefficient sources of energy for driving chemical reactions and melting materials, though they have the advantage of having high-quality light beams that can be shaped and directed as required for many other processes such as cutting and welding metals.

In the past decade, diode stacks that are comprised of one or more laser diodes have become an efficient method of converting electrical energy to coherent light, often achieving over 50% efficiency at some wavelengths. Diode stacks are presently used as the pumping source for fiber and other solid-state lasers. While the phrase “laser diode stack” is commonly understood to comprise a plurality of diodes in a vertically- or horizontally-stacked configuration, laser diodes are available as single laser diode lasers, as well as in configurations other than vertical or horizontal stacks. Embodiments of the present approach may be described herein as featuring one or more laser diode stacks, but it should be appreciated that in some embodiments a single laser diode may provide sufficient power for BNNT synthesis. In other embodiments, a plurality of laser diodes may be in a configuration other than a vertical or horizontal stack, such as, for example, distributed in a circumferential arrangement.

Under the present approach, one or more laser diodes may be used to heat a boron feedstock melt in a chamber, and drive BNNT self-assembly from the boron melt. Some embodiments may feature a plurality of laser diodes in a laser diode stack, and some embodiments may feature more than one laser diode stack. It should be appreciated that other laser diode configurations may be used without departing from the present approach. The beam shape and size generated by the laser diode(s) at the heating location on the boron melt are important parameters in the synthesis of BNNTs under the present approach. These parameters will depend on the particular embodiment, and also may vary over time during processing as described herein. In some embodiments utilizing one or more laser diodes for synthesizing BNNTs, the beam width or height at the heating location may be as small as about 2 mm, to as large as about 30 mm, and larger-scale production apparatus are contemplated that may involve even larger beam cross-sections at the heating location. The beam cross-sectional size will depend on various factors including, for example, the size and type of boron feedstock, the chamber geometry, the processing conditions, and the rate of change in the boron melt volume and cross-sectional shape and area. The embodiments described herein utilize one or more laser diodes, including laser diode stacks, to heat a boron melt for the synthesis of BNNT material, without the need for highly collimated kW class light sources (i.e., lasers) which are complicated and expensive to procure and maintain.

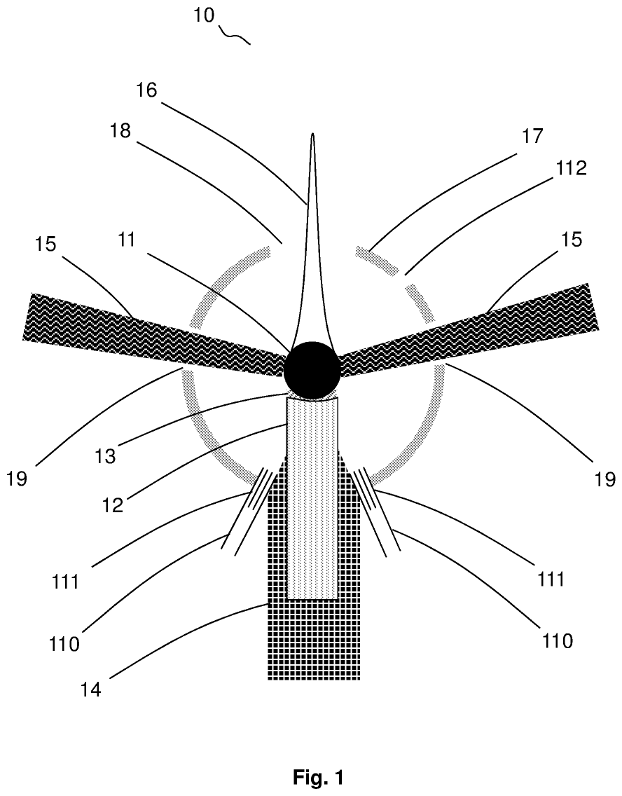

FIG. 1 illustrates one embodiment of a boron target assembly 10 within an apparatus for synthesizing BNNTs using diode stacks. It should be appreciated that nitrogen gas, although not shown, is introduced into the chamber during operation. In this embodiment, a boron melt 11 is present on target assembly 10, where the BNNT self-assembly process is driven by light 15 from two diode stacks (not shown). Although this embodiment It should be appreciated that other embodiments may use one or more laser diodes A boron containing target has been heated to a temperature above boron's melting point to form boron melt 11. The boron melt 11 is supported by a target holder 12 that is adapted to support a boron melt at temperatures above boron's melting point (i.e., over 2,000° C.), such as is described in U.S. Pat. No. 9,745,192, incorporated by reference in its entirety.

A boron nitride-containing layer 13 may be formed or be placed between the boron melt 11 and the target holder 12 during processing. In some embodiments layer 13 may include other nitride species, and/or other boron species, including but not limited to boride compounds. The thermal conductivity of the boron nitride layer 13 provides a path for heat to flow between the boron melt 11 and the target holder 12. The target holder 12 may, in some embodiments, be held in a cooling jacket 14.

As shown in FIG. 1, a vapor plume 16 forms downstream of boron melt 11 in the direction of nitrogen gas flow (not shown) into a growth zone. There may be a variety of boron species in the plume 16 downstream of the boron melt 11, including BNNTs, a-BN, h-BN nanocages, and h-BN nanosheets. The relative amounts of these species are affected by processing parameters including the beam power level on the boron melt, beam shape at the heating location, distribution of power across the boron melt, and the velocity and temperature profiles of the nitrogen gas being fed into the chamber.

The embodiment shown in FIG. 1 includes spherical reflector 17 centered about the boron melt 11. Spherical reflector 17 covers about 27c (50%), and preferably over 37c (75%), of the total 47c solid angle as measured from the center of the boron melt 11. The spherical reflector 17 is configured to reflect light back onto the boron melt 11, primarily light from the diode stacks 15 that is not absorbed by the boron melt 11 and from blackbody radiation that is emitted by the boron melt 11. The shape, space from the target holder 12, and coverage of spherical reflector 17 will depend on the particular embodiment, and a spherical reflector may be optimized for a particular embodiment and, in some instances, for a particular set of processing conditions for a given embodiment. Also, despite the terminology used herein, the shape of the spherical reflector 12 does not have to be exactly spherical, as the shape will depend on the particular embodiment. In some embodiments, for example, the spherical reflector may have slight deviations from an otherwise spherical shape to optimally reflect light back onto the boron melt 11. The shape may approach an oblate spheroid or prolate spheroid. For example, spherical reflector 17 may not approximate a sphere in some embodiments in which the boron melt shape is more ovoid during processing. In some embodiments, spherical reflector 17 may be comprised of separate reflector elements configured to collectively reflect a desired amount of light and/or blackbody radiation. The deviations from spherical should be less than what would result in reflected light not being reflected back on to the boron melt 11, particularly with respect to the light coming off the boron melt 11 normal to the surface of the boron melt. In this embodiment, kW-class light 15 is available from diode stacks in the wavelength range from about 0.4 to about 1.2 microns. It should be appreciated that this wavelength range reflects laser diodes presently available for prototyping, and that other wavelength ranges may be more suitable in later embodiments, particularly as new laser diodes become available in the future. The present approach is not limited to the presently available laser diodes, nor to a particular wavelength or wavelength range unless otherwise stated in a claim.

The spherical reflector 17 may be made from a material having a strong reflectivity at the wavelength of reflected light and black body radiation. In some embodiments, the spherical reflector may be made of copper or a gold-coated material. Copper and gold have better than 98% reflectivity at most of the wavelengths of the light from the diode stacks 15 and at the wavelengths of the blackbody radiation for the indicated temperature range. Silver also has good reflectivity but has undesirable reactions with nitrogen, and aluminum has reflectivity below 90% at some of the wavelengths anticipated to be useful for BNNT synthesis. The spherical reflector 17 may include embedded cooling channels or cooling coils of circulating water (or other coolant) that are not shown, to remove heat from the combination of radiation that is absorbed as well as heat from the nitrogen gas from convective heating and thermal conductivity from the boron melt 11.

The spherical reflector 17 is illustrated in FIG. 1 as being spherical on both the inside and outside of the sphere, however the outside of the spherical reflector 17 can be of any shape convenient for support and channeling the water or other coolant. As those of ordinary skill in the art should appreciate, there are many options for the cooling channels, cooling tubing or other thermal management configurations that may be employed without departing from the present approach.

The spherical reflector 17 shown in the FIG. 1 embodiment includes an opening 18 downstream of the boron melt, in the direction of nitrogen gas flow. Opening 18 allows for the vapor plume 16 to continue downstream of the boron melt 11, for BNNT self-assembly in a growth zone. The size of opening 18 will depend on the embodiment, but in some embodiments will typically be less than 0.57c (12.5%) solid angle, but of sufficient diameter to allow laminar nitrogen gas flow as it exits the spherical reflector 17. The spherical reflector 17 has holes 19 near or slightly above the equator to let in the light from the diode stacks 15. The number of these entrance holes 19 corresponds to the number of diode stack sources of light 15 used. For example, in some embodiments of the present approach two or three diode stacks are used. The size of openings of these holes 19 may be 1-2 mm larger in both transverse horizontal and vertical directions than the size of light from the diode stacks 15, though the size will depend on the particular embodiment. The embodiment shown in FIG. 1 includes a replenishment opening 112 in the spherical reflector 17. The replenishment opening may be between 30 and 60 degrees from vertical in some embodiments, and typically less than 1 cm in diameter for replenishing the boron melt 11 as the BNNT material is synthesized. Though in some embodiments, the angles and boron melt 11 replenishment opening 112 may be beyond this range and larger in size. For some embodiments, there may be at least one circular opening, not shown, near or slightly above the equator of the spherical reflector 17, such that the boron melt 11 can be observed during the BNNT synthesis process. The size of the observation opening depends on the distance from the camera or other tool being utilized, and the size of the boron melt 11 for a given embodiment, and as with many elements of the apparatus may be determined by geometry as those of ordinary skill in the art appreciate.

The configuration of the spherical reflector 17 will largely depend on the particular embodiment. For example, the distance from the top of the boron melt 11 to the interior surface of the spherical reflector 17 should be at least 1 cm, and preferably at least about 2 cm, for most embodiments configured to generate significant volumes of BNNTs. If the distance is beyond 10 cm, then management of the velocity distributions of the nitrogen gas may become more difficult in many embodiments. As the interior space increases, additional multiple toroidal flow cells can be set up with the spherical reflector 17 and the stagnation zone above the melt where nitrogen gas flow is reduced to near zero may get too close to the spherical reflector and the BNNT material in from plume 16 may become difficult to harvest. The spherical reflector 17 can mount on the cooling jacket 14 as illustrated in FIG. 1, but the spherical reflector can also be supported through additional and/or separate mechanical supports, not shown.

The BNNT self-assembly process occurs in the nitrogen gas environment downstream of the boron melt. Boron-containing vapor emerges from the boron melt and interacts with nitrogen downstream of the boron melt, and self-assembly into BNNTs (and other species) proceeds as the reactants proceed downstream in the growth zone. It should be appreciated that the vapor may include various boron species, depending on various factors such as, but not limited to, the starting boron feedstock and the nitrogen gas flow path and pressure, among others. Under the present approach, no catalyst is needed to drive the self-assembly process.

In the FIG. 1 embodiment, nitrogen gas is fed into the spherical reflector 17 from the bottom (e.g., upstream of the boron melt 11) by one or more flow channels 110, which may be, for example, tubes or concentric rings openings. As the flow from channels 110 enters the spherical reflector 117, the fluid passes through flow ducts with variable spacing fins 111. The fins 111 create a laminar flow pattern for the nitrogen gas as it enters the spherical reflector 17 and proceeds towards the boron melt 11. It should be appreciated that other flow modifying structures may be used to generate laminar flow about this region. The nitrogen gas flow field over the boron melt 11 is determined by a combination of the convective heating of the nitrogen gas as it passes over the boron melt, and the velocity distribution of the nitrogen gas. The velocity distribution depends on several factors: the variable spacing fins, the total amount of nitrogen gas being introduced in the spherical reflector, the toroidal shaped flow field of nitrogen gas that results from the heating by the boron melt 11, the volumetric gas flow from the flow channels 110, the cooling of the nitrogen gas on the inside of the spherical reflector 17, and any exterior stagnation zone back pressure on the flow of nitrogen gas coming from the collection of the BNNT material. In some embodiments, the nitrogen gas channels 110 can be eliminated and natural convection alone will determine the flow of nitrogen gas over the boron melt 11. Further, in some embodiments, the spherical reflector 17 can be eliminated, the consequence being that significantly more light from the diode stacks 15 is required to achieve the same level of power going into the boron melt 11. Eliminating the spherical reflector 17 may also have an effect on the nitrogen gas flow in the region of the boron melt. The presence or elimination of any or all of the components to include the spherical reflector 17, nitrogen gas flow channels 110 or concentric rings, and variable spacing fins affect the relative amounts and size distributions of BNNT, amorphous boron particles, a-BN, h-BN nanocages, and h-BN nanosheets. Depending on the specific goals for the BNNT material being produced, different configurations may be required to optimize the relative amounts and characteristics of the indicated materials being synthesized. BNNT purification processes, such as those described in International Patent Application No. PCT/US2017/063729, filed Nov. 29, 2017, and incorporated by reference in its entirety, may be used to further change the relative amounts and size distributions of BNNT, amorphous boron particles, a-BN, h-BN nanocages, and h-BN nanosheets. Various processing conditions may be tuned to synthesis or optimize a desired BNNT material for a given application. Process conditions including, for example, the power and power distribution on the boron melt 11, the size of the boron melt 11, and the nitrogen gas flow to include its velocity and temperature distributions, may be combined with subsequent purification processes, in some embodiments.

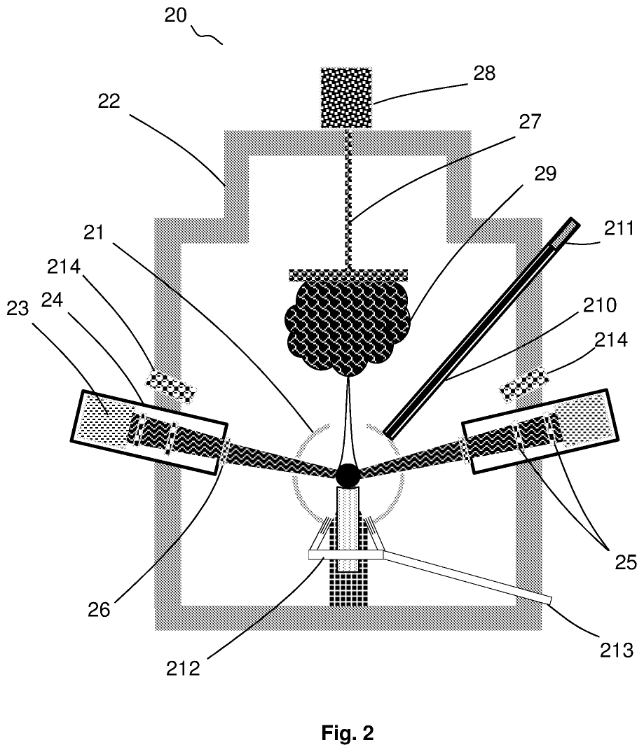

FIG. 2 illustrates one embodiment of a BNNT synthesis apparatus having a boron target assembly 21, such as the embodiment shown in FIG. 1, placed in a nitrogen chamber 22. This embodiment is shown as featuring laser diode stacks 23, but it should be appreciated that other embodiments of the present approach may feature single laser diodes, or multiple laser diodes in other configurations. In the example embodiment, the diode stacks 23 are placed within containers 24 that also include optical shaping element 25 and an exit window 26 that interfaces to the nitrogen gas within the nitrogen chamber 22. The pressure of the nitrogen gas within the nitrogen chamber 22 is typically in the range from about 1 to about 16 atmospheres, and in some embodiments about 1 to about 8 atmospheres, and in some embodiments greater than 1 atmosphere and up to about 8 atmospheres, but in other embodiments the pressure may exceed this range, including pressures as high as 100 atmospheres. Specifying a pressure using the term “about” is intended to convey an approximation, as may be understood in the art. For example, a pressure of about 1 atmosphere may be 0.9 to 1.1 atmospheres. As used herein, the term “elevated pressure” means a pressure between about 2 atmospheres and 100 atmospheres. The operating pressure is a variable that may be adjusted depending on the desired characteristics of the BNNT material to be produced, as described above.

In this embodiment, BNNTs self-assemble from the interaction of nitrogen and boron species in the plume downstream of the boron target assembly 21, to form what is referred to as BNNT material 29, shown as a puff ball. Some embodiments may include one or more mechanisms for collecting and extracting the BNNT material. In this embodiment, for example, a collector 27 with an actuator 28 collects the BNNT material puff ball 29 above the target assembly 21. Embodiments the collector may take the form of a wire mesh, a solid metal sheet, and/or a rotating cylinder, among other configurations. A replenishment tube 210 may be used in some embodiments, to replenish the boron remaining in the target assembly 21, and in this embodiment is driven by an actuator 211. In some embodiments, the boron may be replenished during interruptions in processing.

Some embodiments of the synthesis apparatus may include mechanisms for controlling and/or tuning the flow rate, flow profile, and pressure of nitrogen gas introduced into the chamber 20. In this embodiment, a nitrogen gas manifold 212 is fed by an external source of nitrogen 213 that regulates the nitrogen gas pressure in combination with a nitrogen gas vent, not shown. As those of ordinary skill in the art will appreciate, there is both great flexibility in the design of pressure vessels as well as important safety considerations. For example, the diode stacks 23 with their containers 24, optical shaping elements 25 and windows 26 can be located either completely within the pressure chamber 22, completely external to the pressure chamber 22, or partially within the pressure chamber 22 as illustrated in the embodiment in FIG. 2. It should be appreciated that the mechanical stresses on the windows and the diode stack containers 24, caused by pressurized nitrogen on one side and atmospheric or near atmospheric pressure on the other side, may be evaluated for a given embodiment to determine a suitable configuration for diode stacks 23, containers 24, and optical shaping elements 25. There is also flexibility in the manner of collection of the BNNT material 29. For example, the collector 27 can also be configured to collect the material with a horizontal motion rather than the vertical direction illustrated 27, or as another example, on one or more cylindrical roller(s) or spool(s) that may, if desired, rotate and/or twist as the BNNT material is collected. In addition, cameras or other optical elements 214 can be located to observe and facilitate control of the intersection of the light from the diode stacks 23 on the boron melt 11.

It should also be appreciated that thermal management is an important consideration during operation. With several kilowatts of optical power being fed into the BNNT material synthesis process, many of the elements within the apparatus may require cooling during processing. Typically, water cooling via circulating cooling loops is sufficient to maintain component temperatures within tolerable limits. The multiple cooling loops for the target assembly 21, nitrogen chamber 22, diode stacks 23, and collector 27, etc. are not shown in FIG. 2, but as one of ordinary skill in the art will appreciate, cooling connections can be provided at all locations where heating may occur.

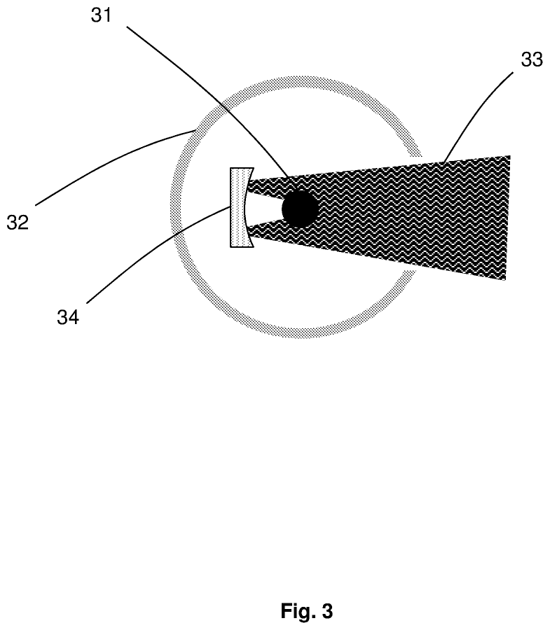

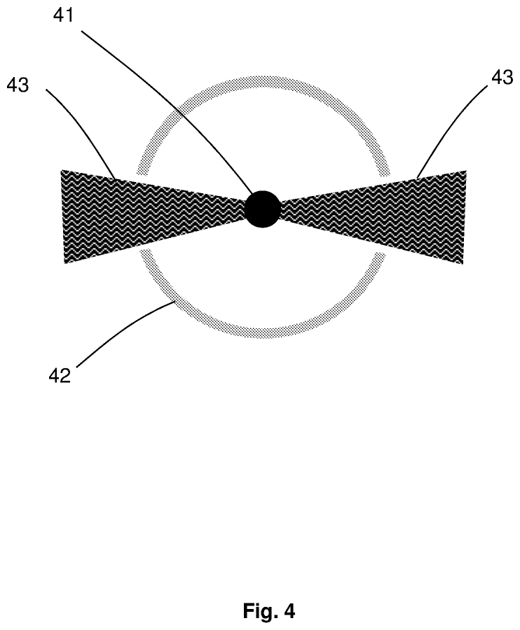

Plan views of two arrangements for supplying light from one or more diode stacks are shown in FIGS. 3 and 4. Again, other embodiments of the present approach may feature one or more laser diodes, and in some embodiments multiple laser diodes configured in arrangements other than as shown in the disclosed embodiments. Light from a single diode stack 33 shaped to intersect on a boron melt 31 in a spherical reflector 32 with a separate reflector 34 is illustrated in the embodiment in FIG. 3. Reflector 34 may be used to prevent boron melt 31 from being forced off the target holder during operation. At the multi-kilowatt power levels of interest for synthesizing BNNT material, there may be sufficient momentum delivered by the light from a laser diode stack to the boron melt 31, to push the boron melt 31 off its target holder. The separate reflector provides sufficient light coming from at least a second direction, and preferably several directions, to keep the boron melt 31 on its support 12 as illustrated in FIG. 1. Use of a separate reflector 34 may be only preferred when only one laser is available.

It should be appreciated that multiple laser diode configurations may be used in embodiments of the present approach. Illustrated in FIG. 4, light from two diode stacks 43 is directed on the boron melt 41 that is located within a spherical reflector 42. The embodiments are not limited to having light from only one or two diode stacks, and three or more sources, in various configurations other than as shown herein, can be utilized. As shown in FIGS. 1 and 2, the light as illustrated in the plan views needs to balance the forces in the horizontal direction on the boron melt 41 or it may be pushed from the support 12 due to the momentum of the light impacting it.

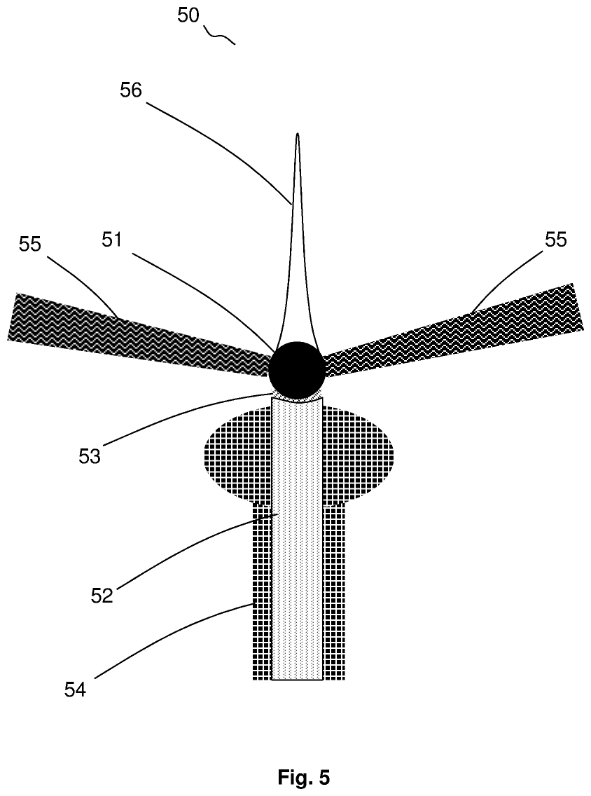

FIG. 5 illustrates an alternate embodiment without a spherical reflector 17 as shown in FIG. 1, and without nitrogen gas tubes 110. In this embodiment, the nitrogen gas flows over the boron melt 51 by natural convection. The support post 52 is held and cooled by the cooling jacket 54. The shape of the cooling jacket 54 may be configured to provide the optimal flow of nitrogen gas over the boron melt 51. For example, the cooling jacket 54 in FIG. 5 has an ovoid shape near the top of the jacket. This shape can be configured to optimize the production of BNNT material self-assembling in plume 56 downstream from boron melt 51.

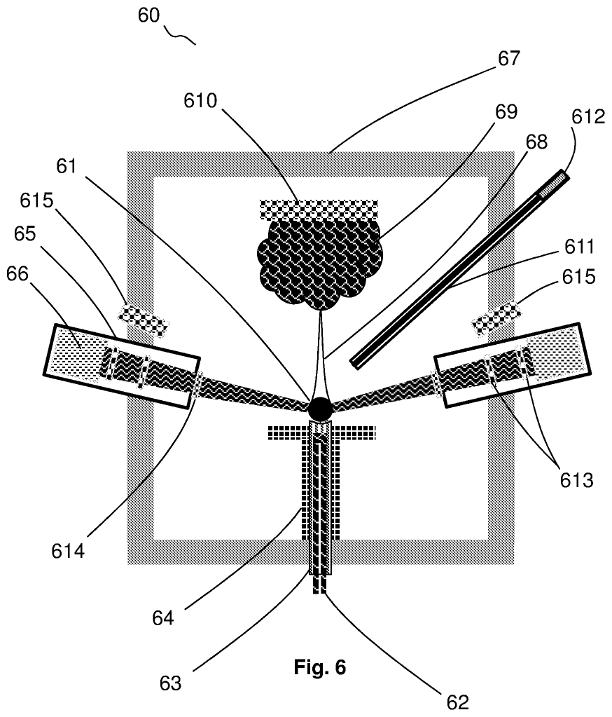

FIG. 6 illustrates an alternative embodiment of a synthesis apparatus 60 without a spherical reflector 17 as shown in FIG. 1, and without additional nitrogen gas tubes 110. Nitrogen gas enters the chamber 67 from an external supply (not shown), from the bottom of the drawing (i.e., upstream of the boron melt 61) and proceeding towards the top of the drawing (i.e., downstream of the boron melt 61). Other components provide flow control to establish and maintain a laminar flow profile of nitrogen gas about the boron melt 61. In this embodiment, a target support for the boron feedstock (and during operation, the boron melt) comprises a support tube 63 with an external nitrogen gas flow control element 64. In some embodiments, the nitrogen flow control element(s) can become heated during operation by a combination of black body radiation from the boron melt 61 and reflected light from the diode stacks 66 in their containers 65. Coolant water (or other cooling fluid) 62 for the support tube 63 circulates through internal channels in the support tube 63. It should be appreciated that, as discussed above, the cooling jackets shown in FIGS. 1 and 5 may operate as a nitrogen flow control element 64, and may be used to control the flow of the nitrogen over the boron melt 61. For example, the flow control element 64 may be shaped to provide for laminar nitrogen gas flow at and above the boron melt. Of course, it should be appreciated that the particular shape will depend on a variety of factors for a given embodiment (e.g., internal volume and geometry, nitrogen gas flow rate into the chamber, power supplied to boron melt, etc.).

As seen in FIG. 6, many of the components of synthesis apparatus 60 are located within a pressure chamber 67, or interfaced to the pressure chamber 67. For example, diode stacks 66 are shown as external to the chamber 67, but diode stack containers 66 extend through the chamber walls and into the interior volume. It should be appreciated that alternative configurations are possible, without departing from the present approach. During operation, the BNNT material 69 self-assembles in and above the vapor plume 68, downstream from the boron melt 61. The term ‘downstream’ is used in relationship to the direction of flow in the apparatus 67. In some embodiments, the direction of flow is determined by the direction of nitrogen gas flowing into the apparatus. In FIG. 6, for instance, nitrogen gas enters from the bottom of the drawing, and proceeds toward the top of the drawing. The nitrogen gas flow profile shapes the boron vapor plume 68, and as discussed herein, the vapor plume is downstream of the boron melt 61. BNNT self-assembly occurs as nitrogen interacts with the vapor plume 68, which is also downstream of the boron melt 61. Unlike prior synthesis methods, BNNTs are not forming on the surface of the boron feedstock. In the present approach, the boron feedstock is heated into liquid form, referred to as a boron melt, and boron atoms, in various species, available for reacting with nitrogen are forced upwards (i.e., downstream of the boron melt 61) by the nitrogen gas flow and, in some embodiments, forces generated by the temperature profile in the chamber. Also, unlike prior synthesis methods, the present approach does not require a condenser or other surface to induce BNNT formation. Instead, the nanotubes self-assemble as they proceed downstream from the boron feedstock 61. Nanotube length and orientation may be controlled through the temperature and velocity profiles along the self-assembly path, as discussed in International Patent Application No. PCT/US15/027,570, filed Apr. 24, 2015 and incorporated by reference in its entirety.

It should be appreciated that various BNNT collection mechanisms are contemplated under the present approach. In the embodiment shown in FIG. 6, for example, the BNNT material 69 is collected on a collection grid or plate 610 downstream from the boron melt 61 and plume 68. In some embodiments, the collection mechanism may remain stationary during operation, whereas in others the collection mechanism may move during operation. For example, in some embodiments the collection mechanism may comprise cylindrical spool(s) that rotate about an axis perpendicular to the BNNT self-assembly direction, to wind BNNTs during collection. As another example, the embodiment illustrated in FIG. 6 features a collection grid or plate 610 configured to move horizontally into or out of the plane of the illustration. A layer of BNNT material may collect on the surface of collection grid or plate 610, and the thickness and density of the layer may be controlled by the rate at which collection grid or plate 610 translates during operation. The BNNT layer may be removed from collection grid or plate 610 on an ongoing basis during operation, or during interruption(s) from operation. The embodiment of BNNT material 69 collection mechanism 610 may be chosen by determining how the BNNT material 69 will be harvested or separated from the collection mechanism 610. For example, a smooth metal surface is preferred if the BNNT material 69 is scraped from the collection mechanism 610 while a screen may be preferred if the BNNT material is mechanically pulled from the collection mechanism 610. As BNNT material 69 is synthesized, the size and mass of the remaining boron melt 61 decreases. Boron can be replenished during operation (or during brief interruptions in operation) by injecting additional boron feedstock. A variety of feedstock replenishment systems are contemplated. For example, the boron feeder 611 and actuator 612 may be internal to the pressure chamber 67, or partially internal to the pressure chamber 67 as illustrated in the FIG. 6 embodiment.

Diode stack containers 65 may include one or more optical elements 613, 614, to shape the light and control the power distribution on the boron melt 61 where the light intersects the boron melt 61. Optical shaping elements may include reflective, refractive, light fiber, diffraction grating, polarization, absorptive and beam splitting elements. Power distribution, beam shape at the heating location, and intersection area on the boron melt 61, i.e., the overall power level being generated by the diode stacks 66, and the size of the light generation face of the diode stacks 66, will depend on the particular embodiment.

It should also be appreciated that the processing conditions may change during operation. For example, the mass and volume of the boron melt 61 changes during operation, as vapor emerges. The cross-sectional profile or area of the boron melt 61 may also change over time during operation. The diode stack 66 power level and optics 612 and 614 may be adjusted during operation to account for these changing conditions, particularly as the boron melt 61 decreases in size during a run segment. For example, the beam shape and/or size at the heating location may be changed during operation as a function of the boron melt 61 mass, volume, cross-sectional profile, and/or area. Further, the diode stacks 66 can be adjusted to couple with changes in nitrogen gas flow from the flow tubes 110 and flow control elements 64.

One advantage that diode stacks 66 provide over other light sources (e.g., lasers other than laser diodes such as fiber-coupled lasers, and CO₂ lasers) is that laser diodes and configurations such as diode stacks provide the ability to selectively adjust power distributions of the entire region being illuminated on the boron melt in real-time. In some embodiments the boron may be replenished, and the rate of replenishment may depend on the particular embodiment. The rate of replenishment may match the rate of consumption or may be at discrete intervals. During the course of a run segment (e.g., between boron replenishment), the boron melt changes in mass and shape due to the production of boron-containing vapor in the plume that results in the formation of BNNT material.

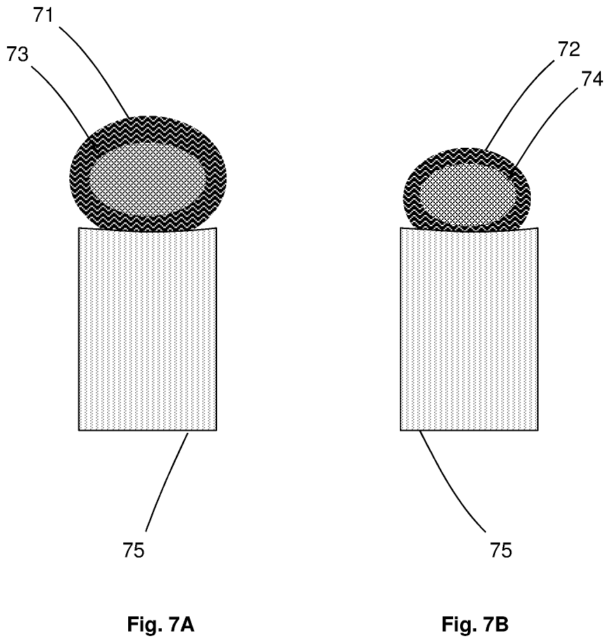

Consistent production, particularly for high-quality BNNT material, may be achieved through real-time beam manipulation (e.g., power, beam shape at the heating location, power distribution across the heating location, etc.) as a function of changes to the boron melt. The power distribution may be monitored during operation by, for example, cameras or other optical elements 615, and the beam may be adjusted during a run segment. For example, when the light from diode stacks 66 begins to miss portions of the boron melt 61 due to the decrease in boron melt size during the run segment, the beam cross-section at the heating location may be reduced to correspond. The reduction in beam cross-section may be accomplished by changing the position of one or more of the optical elements. The power of the beam may also be changed. In some embodiments, the beam may be manipulated as a function of time of operation. FIGS. 7A and 7B illustrate a simplified view of one embodiment in which the laser diode beam is manipulated during processing. FIG. 7A shows boron melt 71 on the support target holder 75 at an initial time T1, and FIG. 7B shows boron melt 72 on the support target holder 75 at subsequent time T2. Boron melt at T1 has a spherical or ovoid shape, and the light beam from one or more laser diodes (not shown) intersects at heating location 73. As the run segment progresses to time T2, the boron melt 72 has decreased in size and the shape has changed. Consequently, the light beam has been manipulated to decrease its cross-sectional area to target location 74. As a simplified example, one or more optical elements may have been moved closer to the target holder 75. Those of ordinary skill in the art will appreciate that the beam may be manipulated in various ways, depending upon the particular embodiment. In addition, the level of power from the laser diode(s) (not shown) and/or the detailed distribution of the power on the boron melt 72 may have been adjusted, to continue BNNT self-assembly and synthesize the desired BNNT material. Those of ordinary skill in the art will appreciate that the power level and distribution may be adjusted real-time, separately or in conjunction with beam cross-sectional area or shape changes, and that the beam may be manipulated in various ways, other than as shown in connection with the various embodiments described herein. It should also be appreciated that the nitrogen gas flow rates and pressure may be adjusted as well. These various parameters may be tuned during operation to consistently generate the desired BNNT material.

Such real-time manipulation for other light sources, such as fiber-coupled lasers and CO₂ lasers, is not practically feasible, given at least the complexity and cost of such real-time and precise manipulations. With laser diodes, on the other hand, real-time beam manipulation is both efficient and effective.

Further improvements in laser diode technology are expected to provide further opportunities to increase the production efficiency and quality. As discussed herein, laser diode(s) and, in particular, diode stacks, provide a cost-effective technology for the synthesis of high quality BNNT material. Prototype production apparatus have been used to synthesize high quality BNNT material using the three different light sources listed in Table 1, below. The relative cost efficiency is calculated as the BNNT material production rate divided by the capital cost of the light source normalized to the diode stack having a relative efficiency of 1. If the relative amounts of electric power required had also been included, the relative efficiency value for the CO₂ laser would be even lower. The power level of light incident on the boron melt (not the input electrical power) was set to be the same power value in kW for each light source for comparison purposes. Additionally, the power level of light was set to produce material having optimal amount of BNNT relative to non-BNNT species with the mass of BNNT typically greater than 50 wt % of the BNNT material. The optical conditions, boron melts, nitrogen gas flows, and supports for the boron melts were separately optimized for each light source, so as to produce the maximum amounts of high quality BNNT material for the same amount of light power.

TABLE 1
Relative efficiency of various light
sources in the production of BNNTs.

| | BNNT Production Relative Cost Efficiency |
|---|---|
| Light source | for High Quality BNNT Material |
| Diode Stack | 1 |
| Fiber coupled laser | 0.06 |
| CO₂ laser | 0.008 |

Those of ordinary skill in the art should appreciate that embodiments of the present approach significantly depend on the detailed geometry of the diode(s), boron melt(s), and BNNT material collection mechanism. The BNNT material resulting from a particular synthesis process will have a variety of parameters, ranging from diameter and length averages to impurity (i.e., non-BNNT species) content. Such parameters may vary for different synthesis processes. Those parameters, in turn, will likely impact the post-synthesis processing, such as, for example, purification steps, compression and shaping, etc. The examples described herein are provided as demonstrative, and should not be understood as limiting the scope of the present approach.

The terminology used herein is for the purpose of describing particular embodiments only and is not intended to be limiting of the approach. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present approach may be embodied in other specific forms without departing from the spirit or essential characteristics thereof. The disclosed embodiments are therefore to be considered in all respects as illustrative and not restrictive, the scope of the present approach being indicated by the claims of the application rather than by the foregoing description, and all changes which come within the meaning and range of equivalency of the claims are therefore intended to be embraced therein. One of ordinary skill in the art should appreciate that numerous possibilities are available, and that the scope of the present approach is not limited by the embodiments described herein.

1. A laser diode apparatus for producing boron nitride nanotube (BNNT) materials, the apparatus comprising:
a chamber having a boron feedstock mounting surface, the mounting surface configured to support a boron melt;
a nitrogen gas supply system configured to feed nitrogen gas into the chamber upstream of the mounting surface, and flow the nitrogen gas through the chamber in a first direction;
at least one laser diode configured to emit a beam into the chamber and irradiate a heating location on a boron melt on the mounting surface at a selected power, wherein the selected power is adjustable;
at least one optical shaping element configured to adjust the cross-section of the beam at the heating location;
a growth zone region downstream of the mounting surface in the first direction, the growth zone region configured for BNNT self-assembly downstream of the mounting surface in the first direction.

2. The laser diode apparatus of claim 1, wherein the at least one laser diode comprises a plurality of laser diodes.

3. The diode apparatus of claim 2, wherein the plurality of laser diodes comprises a laser diode stack.

4. The diode apparatus of claim 1, wherein the at least one laser diode comprises a plurality of laser diodes stacks.

5. The laser diode apparatus of claim 1, wherein the at least one optical shaping element comprises a refractive optical element.

6. The laser diode apparatus of claim 1, wherein the at least one optical shaping element comprises a fiber optic element.

7. The laser diode apparatus of claim 1, wherein the at least one optical shaping element comprises a reflective optical element.

8. The laser diode apparatus of claim 1, further comprising a spherical reflector positioned around at least a portion of the mounting surface and configured to reflect at least one of light and blackbody radiation toward a region downstream of the mounting surface.

9. The laser diode apparatus of claim 8, wherein the spherical reflector comprises at least one nitrogen gas flow channel upstream of the mounting surface and configured to direct nitrogen gas in the first direction.

10. The laser diode apparatus of claim 1, further comprising a BNNT material harvesting mechanism.

11. The laser diode apparatus of claim 10, wherein the harvesting mechanism comprises at least one of a wire mesh, a metal sheet, and a rotating cylinder.

12. The laser diode apparatus of claim 1, further comprising a boron nitride-containing layer on the mounting surface.

13. A laser diode process for synthesizing boron nitride nanotube (BNNT) material, the process comprising:
feeding nitrogen gas to a chamber in a first direction and at a flow rate;
forming a boron melt on a mounting surface;
irradiating a first heating location of the boron melt with a beam from at least one laser diode, the beam comprising a beam power and a beam cross-section at the heating location;
collecting BNNT material comprising BNNTs that self-assemble downstream of the boron melt;
adjusting at least one of the flow rate, the beam power, and the beam cross-section during the irradiation, the adjustment corresponding to consumption of the boron melt.

14. The process of claim 13, further comprising forming a boron nitride-containing layer on the mounting surface.

15. The process of claim 13, further comprising replenishing the boron melt with a boron feedstock.

16. The process of claim 13, wherein adjusting at least one of the flow rate, the beam power, and the beam cross-section during the irradiation comprises changing the position of at least one optical shaping element.

17. The process of claim 16, wherein the at least one optical shaping element comprises a refractive optical element.

18. The process of claim 16, wherein the at least one optical shaping element comprises a fiber optic element.

19. The process of claim 16, wherein the at least one optical shaping element comprises a reflective optical element.

20. The process of claim 13, further comprising reflecting at least one of light and blackbody radiation onto the boron melt.

21. The process of claim 20, wherein reflecting at least one of light and blackbody radiation comprises at least one spherical reflector having at least one nitrogen gas flow channel upstream of the mounting surface and configured to direct nitrogen gas in the first direction.

22. The process of claim 13, wherein the at least one laser diode comprises a plurality of laser diodes.

23. The process of claim 20, wherein the plurality of laser diodes comprises a laser diode stack.

24. The process of claim 13, further comprising irradiating a second heating location of the boron melt with a second beam from a second laser diode, the second beam having a second beam power and a second beam cross-section.

25. The process of claim 24, wherein the second laser diode comprises a laser diode stack.

26. The process of claim 24, further comprising adjusting at least one of the second laser diode beam power and the second laser diode beam cross-section during the irradiation.

27. The process of claim 26, wherein adjusting at least one of a second laser diode beam power and a second laser diode beam cross-section during the irradiation comprises changing the position of a second optical shaping element.

28. The process of claim 26, further comprising adjusting the beam power of the at least one laser diode and adjusting the second beam power.

29. The process of claim 26, further comprising adjusting the beam cross-section of the at least one laser diode and adjusting the second beam cross-section.

30. The process of claim 26, further comprising reflecting at least one of light and blackbody radiation onto the boron melt.

31. The process of claim 30, wherein reflecting at least one of light and blackbody radiation comprises a spherical reflector having at least one nitrogen gas flow channel upstream of the mounting surface and configured to direct nitrogen gas in the first direction.

32. The process of claim 13, further comprising replenishing boron in the boron melt.

33. The process of claim 32, further comprising adjusting at least one of the flow rate, the beam power, the beam cross-section, the second beam power, and the second beam cross-section, the adjustment corresponding to the replenishment of boron in the boron melt.
